(19) United States
(12) Patent Application Publication
(10) Pub. No.: US 2025/0374577 A1
(43) Pub. Date: Dec. 4, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Kuo-Chang Chiang, Hsinchu City (TW); Chih-Yu CHANG, New Taipei City (TW); Hsin-Yu LAI, Hsinchu (TW); Katherine H. CHIANG, New Taipei City (TW); Yan-Yi Chen, Taipei City (TW)

(73) Assignee: Taiwan Semiconductor Manufacturing Company, Ltd., Hsinchu (TW)

(21) Appl. No.: 18/679,331

(22) Filed: May 30, 2024

(51) Int. Cl. H01L 29/66; H01L 21/324; H01L 25/065; H01L 29/20; H01L 29/778

(52) U.S. Cl. CPC H10D 30/015; H01L 21/3245; H01L 25/0657; H10D 30/475; H10D 62/8503; H01L 2225/06541

(57) ABSTRACT

A semiconductor structure includes an interconnect structure over a substrate and a transistor embedded in the interconnect structure. The transistor includes at least one gate layer, a gate dielectric layer extending along the at least one gate layer, a channel layer extending along the gate dielectric layer, a heterostructure interposed between the gate dielectric layer and the channel layer, and source/drain vias connected to the channel layer. The heterostructure includes a two-dimensional electron gas region acting as a part of a channel of the transistor.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. Although existing semiconductor structures have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor structure, in accordance with some embodiments.

FIGS. 2A-2G illustrate schematic cross-sectional views of intermediate steps during a process for forming a second semiconductor device in FIG. 1, in accordance with some embodiments.

FIG. 3 illustrates a schematic perspective view of a second semiconductor device in a semiconductor structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As metal oxide semiconductor field effect transistor (MOSFET) feature sizes decrease, the gate oxide thickness of the device also decreases. However, the extremely thin gate oxide results in the increased gate-to-channel leakage current. Problems such as this have led to the use of gate dielectrics having a high dielectric constant (e.g., high-k dielectrics) to maintain device performance. However, high-k dielectrics contain a greater number of bulk traps and interface traps than gate dielectrics made of silicon dioxide and may lead to a negative shift of the threshold voltage (Vt) of the device and leak path formation into the channel layer of the device. Thus, reducing carrier concentration in the channel layer with good gate control is present but limits the high electron mobility transistor (HEMT) application. Compared with MOSFETs, HEMTs may have a number of attractive properties such as high electron mobility, the ability to transmit signals at high frequencies, etc. A high electron mobility transistor (HEMT) is a field effect transistor which may include a two-dimensional electron gas (2 DEG) close to a junction (also called “heterojunction”) between two different metal oxide materials.

Embodiments discussed herein are to provide a semiconductor structure having a back-end semiconductor device and methods for forming the same. For example, the back-end semiconductor device is a transistor (e.g., a HEMT) which includes a 2 DEG region serving as a part of the channel of the transistor. The 2 DEG region may include highly mobile conducting electrons with very high densities. The 2 DEG region may maintain good interfacial quality between the channel layer and the gate dielectric layer and may prevent interaction between the channel layer and the gate dielectric layer. The interfaces among the channel layer, the 2-DEG layer, and the gate dielectric layer remaining heterogeneous is beneficial for less interface traps, leading good bias stress reliability. In addition, the 2 DEG region may be formed compatible with the back-end-of-line (BEOL) processes.

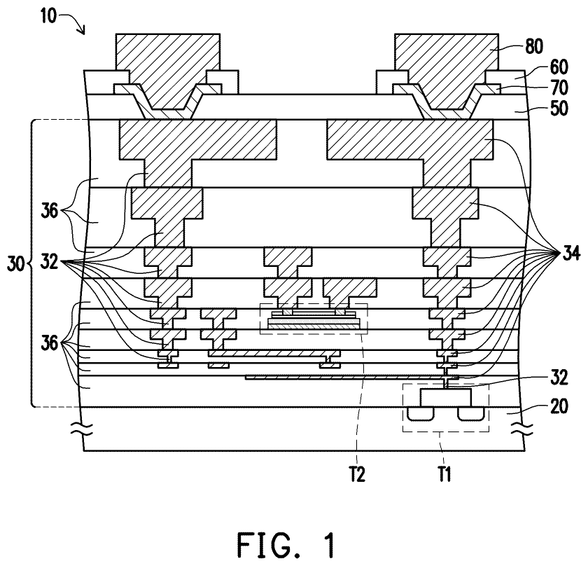

FIG. 1 illustrates a schematic cross-sectional view of a semiconductor structure, in accordance with some embodiments. Referring to FIG. 1, a semiconductor structure 10 may include a substrate 20, an interconnection structure 30, a passivation layer 50, a post-passivation layer 60, conductive pads 70, and conductive terminals 80. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions are doped with p-type or n-type dopants. In some embodiments, these doped regions serve as source/drain (S/D) regions of a first semiconductor device T1 formed in the substrate 20. Note that S/D region(s) may refer to a source or a drain, individually or collectively dependent upon the context. Depending on the types of the dopants in the doped regions, the first semiconductor device T1 may be referred to as an n-type transistor or a p-type transistor. In some embodiments, the first semiconductor device T1 further includes a metal gate and a channel under the metal gate. The channel is located between the source region and the drain region to serve as a path for electrons to travel when the first semiconductor device T1 is turned on. In some embodiments, the first semiconductor device T1 is formed using suitable Front-end-of-line (FEOL) process. Depending on the circuit requirements, the first semiconductor device T1 may be completely embedded in the substrate 20 or partially embedded in the substrate 20. For simplicity, a single first semiconductor device T1 is shown in FIG. 1. However, it should be understood that more than one first semiconductor device T1 may be embedded in the substrate 20 depending on the application of the semiconductor structure 10. When multiple first semiconductor devices T1 are presented, these first semiconductor devices T1 may be separated by shallow trench isolation (STI; not shown) located between two adjacent first semiconductor devices T1. For example, the STI are also embedded in the substrate 20.

With continued reference to FIG. 1, the interconnection structure 30 is formed on the substrate 20. In some embodiments, the interconnection structure 30 includes conductive vias 32, conductive patterns 34, dielectric layers 36, and one or more second semiconductor devices T2. The conductive patterns 34 may be embedded in the dielectric layers 36. The conductive vias 32 may each penetrate through the dielectric layers 36. In some embodiments, the conductive patterns 34 located at different level heights are connected to one another through the conductive vias 32. For example, the conductive patterns 34 are electrically connected to one another through the conductive vias 32. In some embodiments, the bottommost conductive vias 32 are connected to the first semiconductor device T1 embedded in the substrate 20 and establish electrical connection between the first semiconductor device T1 and the conductive patterns 34 of the interconnection structure 30. For example, the bottommost conductive via 32 is connected to the metal gate of the first semiconductor device T1 and may be referred to as the gate contact of the first semiconductor device T1. It should be noted that in some alternative cross-sectional views, the bottommost conductive vias 32 are also connected to S/D regions of the first semiconductor device T1 and may be referred to as the S/D contacts of the first semiconductor device T1.

In some embodiments, a material of the dielectric layers 36 includes oxide (e.g., SiO₂ or the like), a nitride (e.g., SiN or the like), an oxynitride (e.g., SiON or the like), other high-k dielectrics, combinations thereof, and/or the like. In other embodiments, the dielectric layers 36 include polyimide, epoxy resin, acrylic resin, phenol resin, benzocyclobutene (BCB), polybenzooxazole (PBO), or any other suitable polymer-based dielectric material. The dielectric layers 36 may be formed by suitable fabrication techniques such as spin-on coating, chemical vapor deposition (CVD), plasma-enhanced chemical vapor deposition (PECVD), or the like. Material(s) of the conductive patterns 34 and the conductive vias 32 may include Al, Ti, Cu, Ni, W, alloys thereof, combinations thereof, or the like. The conductive patterns 34 and the conductive vias 32 may be formed by electroplating, deposition, lithography and etching, and/or any suitable process. In some embodiments, the conductive patterns 34 and the underlying conductive vias 32 are formed simultaneously through a dual damascene process. It should be noted that the number of the dielectric layers 36, the number of the conductive patterns 34, and the number of the conductive vias 32 illustrated in FIG. 1 are merely for illustrative purposes, and the disclosure is not limited thereto. Fewer or more layers of the dielectric layers 36, the conductive patterns 34, and/or the conductive vias 32 may be formed depending on the circuit design.

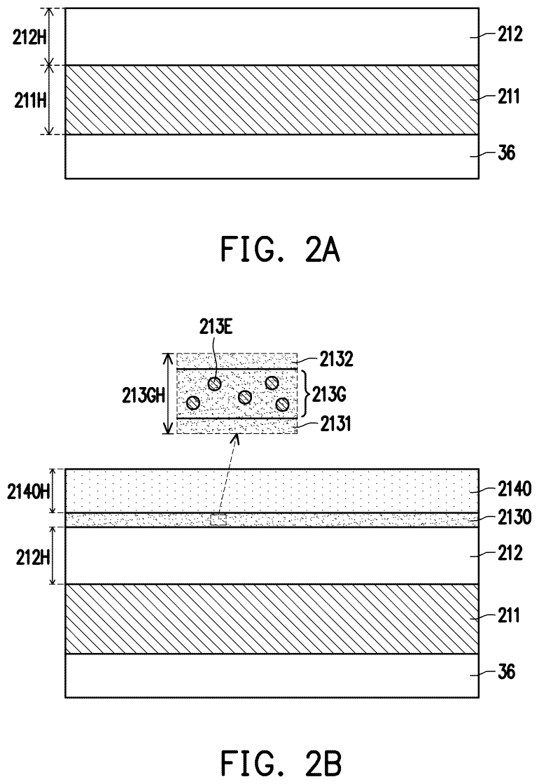

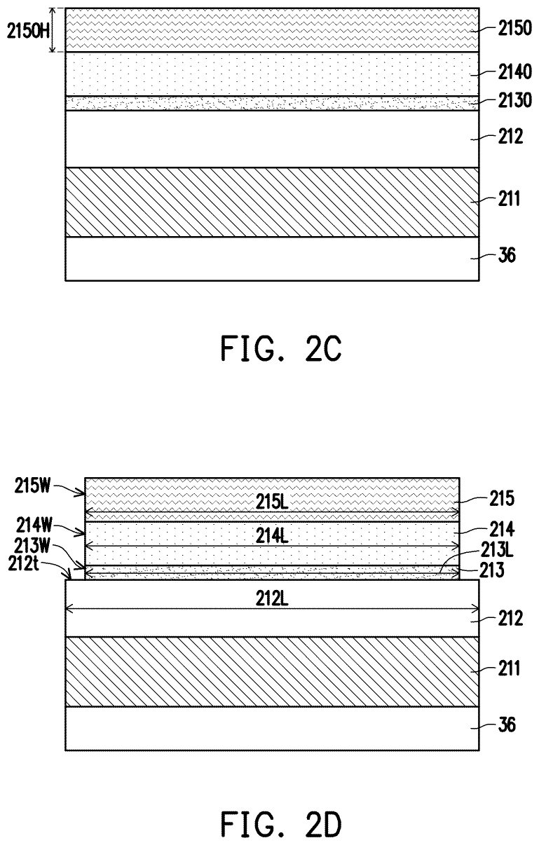

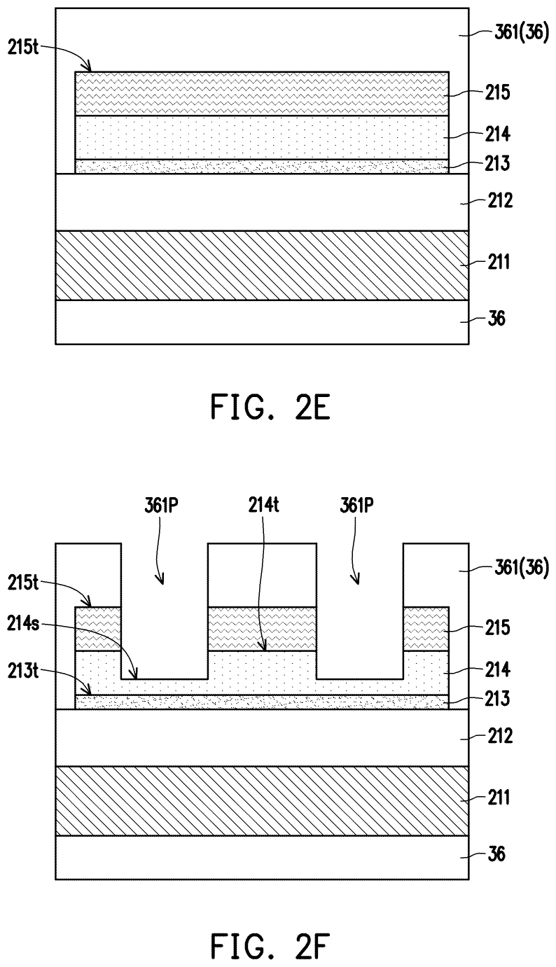

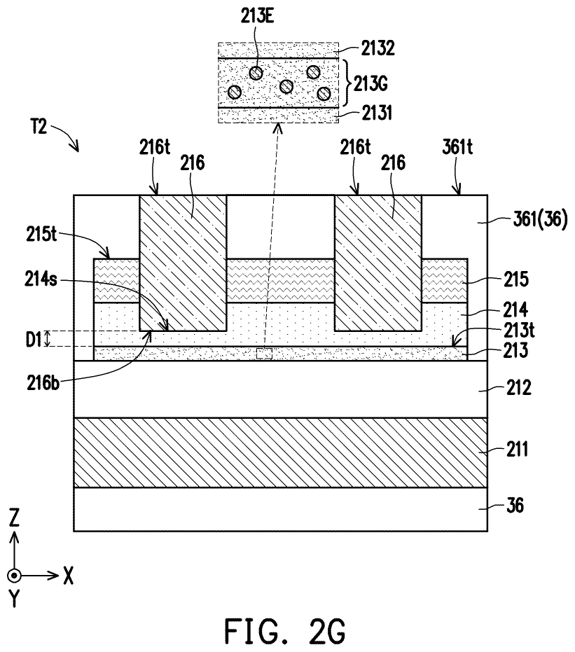

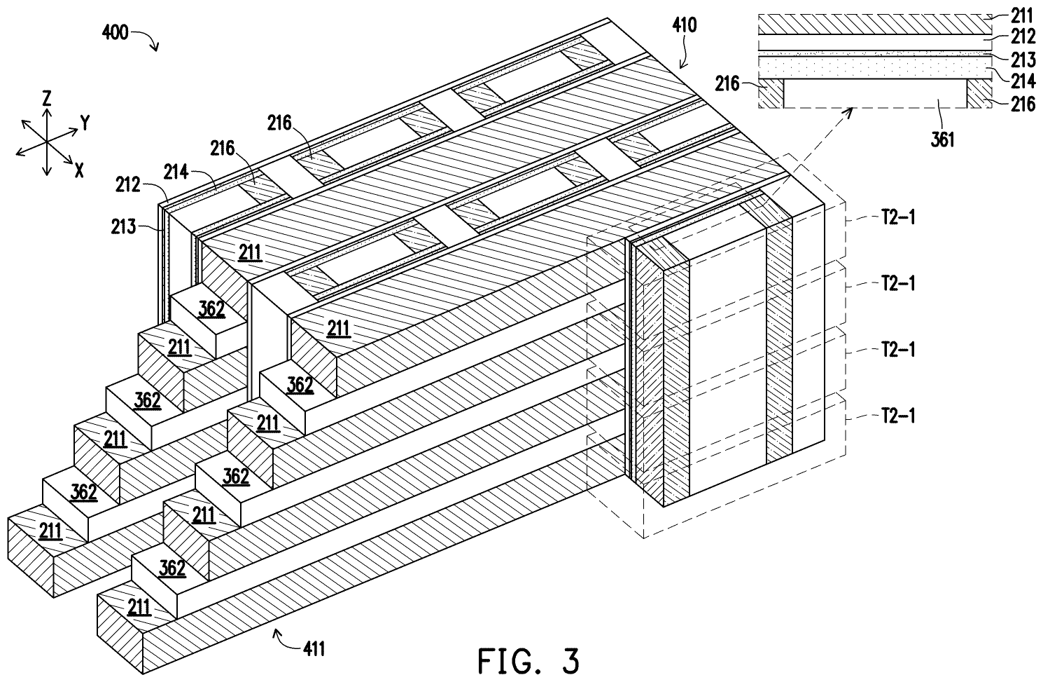

With continued reference to FIG. 1, the second semiconductor devices T2 may be embedded in one or more dielectric layers 36 of the interconnection structure 30. In some embodiments, the second semiconductor device T1 is formed using suitable BEOL process. The formation method and the detailed structure of the second semiconductor devices T2 will be described in detail later in accompanying with FIGS. 2A-3. In some embodiments, the passivation layer 50, the conductive pads 70, the post-passivation layer 60, and the conductive terminals 80 are sequentially formed on the interconnection structure 30. In some embodiments, the passivation layer 50 is disposed on the topmost dielectric layer 36 and the topmost conductive patterns 34. In some embodiments, the passivation layer 50 has openings partially exposing the topmost conductive pattern 34. The passivation layer 50 may be or include silicon oxide, silicon nitride, silicon oxy-nitride, or any suitable dielectric materials, and may be formed by suitable fabrication techniques such as HDP-CVD, PECVD, or the like.

With continued reference to FIG. 1, the conductive pads 70 may be formed over the passivation layer 50. In some embodiments, the conductive pads 70 extend into the openings of the passivation layer 50 to be in direct contact with the topmost conductive patterns 34. The conductive pads 70 may be electrically connected to the interconnection structure 30. In some embodiments, the conductive pads 70 include aluminum pads, copper pads, titanium pads, or other suitable metal pads. The conductive pads 70 may be formed by electroplating, deposition, lithography and etching, and/or any suitable process. It should be noted that the number and the shape of the conductive pads 70 illustrated herein are merely for illustrative purposes, and the disclosure is not limited thereto. The number and the shape of the conductive pad 70 may be adjusted based on demand. In some embodiments, the post-passivation layer 60 is formed over the passivation layer 50 and the conductive pads 70. The post-passivation layer 60 may be formed on the conductive pads 70 to protect the conductive pads 70. In some embodiments, the post-passivation layer 60 has contact openings partially exposing the conductive pads 70. The post-passivation layer 60 may be or include polyimide, PBO, BCB, or any suitable polymer, and may be formed by suitable fabrication techniques such as HDP-CVD, PECVD, or the like.

The conductive terminals 80 may be formed over the post-passivation layer 60 and the conductive pads 70. In some embodiments, the conductive terminals 80 extend into the contact openings of the post-passivation layer 60 to be in direct contact with the corresponding conductive pad 70. The conductive terminals 80 may be electrically connected to the interconnection structure 30 through the conductive pads 70. In some embodiments, the conductive terminals 80 are conductive pillars, conductive posts, conductive balls, conductive bumps, or the like. In some embodiments, a material of the conductive terminals 80 includes a variety of metals, metal alloys, or metals and mixture of other materials. For example, the conductive terminals 80 may be made of Al, Ti, Cu, Ni, W, Sn, and/or alloys thereof. The conductive terminals 80 are formed by deposition, electroplating, screen printing, or any suitable methods. In some embodiments, the conductive terminals 80 are used to establish electrical connection with other components (not shown) subsequently formed or provided.

It should be noted that FIG. 1 is provided for illustrative purposes only, and the semiconductor structure 10 may utilize fewer or additional elements according to some embodiments. One or more packaging/semiconductor process may be performed on the semiconductor structure 10 depending on product requirements. The advanced packaging technologies enable production of semiconductor structure 10 with enhanced functionalities. The embodiments described herein are not intended to be limited to the embodiments described, and the embodiments may be implemented in any suitable methods and structures (e.g., integrated fanout packages, package-on-package, chip-on-wafer-on-substrate packages, system-on-integrated-circuit structure, etc.). All such embodiments are fully intended to be included within the scope of the embodiments.

FIGS. 2A-2G illustrate schematic cross-sectional views of intermediate steps during a process for forming the second semiconductor device T2 in FIG. 1, in accordance with some embodiments. For simplicity, portions of the semiconductor structure below the second semiconductor device T2 are omitted in FIGS. 2A-2G. It is understood that additional operations may be provided before, during, and after processes shown by FIGS. 2A-2G, and some of the operations described below may be replaced or eliminated, for additional embodiments of the method. The order of the operations/processes may be interchangeable. The second semiconductor device depicted in the following paragraphs may be used as the second semiconductor device in FIG. 1. Like reference numerals denote like features with similar structures and compositions.

Referring to FIG. 2A and with reference to FIG. 1, a gate layer 211 may be formed on one of the dielectric layers 36. In some embodiments, the gate layer 211 is formed on top surfaces of the dielectric layer 36 and the conductive pattern 34 (not shown in FIG. 2A but can refer to FIG. 1) covered by the dielectric layer 36, where the gate layer 211 is in physical and electrical contact with the conductive pattern 34. In alternative embodiments, the gate layer 211 is formed on top surfaces of the dielectric layer 36 and the conductive via 36 (not shown in FIG. 2A but can refer to FIG. 1) covered by the dielectric layer 36, where the gate layer 211 is in physical and electrical contact with the conductive via 32. The gate layer 211 may include one or more conductive material(s) such as Ti, W, Ta, Mo, Al, nitride thereof (e.g., TaN, TiN, or the like), alloy thereof, combinations thereof, and/or the like. The gate material may be formed and patterned on the dielectric layers 36 to form the gate layer 211 through any suitable deposition and patterning processes. In some embodiments, the gate layer 211 is formed with a thickness 211H ranging from about 50 angstroms to about 500 angstroms. It is realized that the thickness range is an example, and may be changed to other suitable values depending on product requirements.

With continued reference to FIG. 2A, a gate dielectric layer 212 may be formed on the gate layer 211. The gate dielectric layer 212 may be formed by CVD, physical vapor deposition (PVD), atomic layer deposition (ALD), or any suitable deposition process. The gate dielectric layer 212 may be deposited either in-situ or ex-situ. The material of the gate dielectric layer 212 may include HfO₂, HZO, Al₂O₃, ZrO₂, HfZrO, HfLaO, HfSiO, HfTiO, or dielectrics having dielectric constants greater than 6 or 9, combinations thereof, etc. In some embodiments, the gate dielectric layer 212 is formed with a thickness 212H ranging from about 30 angstroms to about 150 angstroms. It is realized that the thickness range is an example, and may be changed to other suitable values depending on product requirements.

Referring to FIG. 2B and with reference to FIG. 2A, a stack of a heterostructure 2130 and a channel material layer 2140 may be formed on the gate dielectric layer 212. The heterostructure 2130 may include at least two different materials, wherein these two materials may have different crystalline lattice sizes, different energy band gaps, different lattice constants, and/or other different material properties. For example, the heterostructure 2130 includes a lower metal oxide material 2131 overlying the gate dielectric layer 212 and an upper metal oxide material 2132 overlying the lower metal oxide material 2131 and different from the upper metal oxide material 2132. The heterostructure 2130 may include two or more metal oxide materials.

With continued reference to FIG. 2B, the heterostructure 2130 include an intermixing region between the upper and lower metal oxide materials (2132 and 2131) for the formation of a two-dimensional electron gas (2 DEG) region 213G, where free electrons 213E in the heterostructure 2130 may travel along the 2 DEG region 213G which serves as the main transport path in the heterostructure 2130. The 2 DEG region 213G may be formed at (or close to) a junction between the upper and lower metal oxide materials (2132 and 2131). The junction may be referred to as a heterojunction. For example, the formation of the 2 DEG region 213G is induced by oxygen vacancies, and upon introducing oxygen vacancies, the heterojunction of the heterostructure 2130 becomes conducting. The 2 DEG region 213G may act as on-current boost for channel tunneling. In some embodiments, the effective thickness 213GH of the 2 DEG region 213G is in a range of about 10 angstroms to about 30 angstroms. The effective thickness 213GH of the 2 DEG region 213G may be in a range of about 80% and about 100% of the overall thickness of the heterostructure 2130. It is realized that the thickness range is an example, and may be changed to other suitable values depending on product requirements.

The heterostructure 2130 may be an In₂O₃/Al₂O₃ heterostructure, a ZnO/SnO₂ heterostructure, a TiO₂/Al₂O₃ heterostructure, an InSnO/ZrO₂ heterostructure, an In₂O₃/ZrO₂ heterostructure, an In₂O₃/InMgO heterostructure, a Ga₂O₃/Sc₂O₃ heterostructure, a LaAlO₃/SrTiO₃ heterostructure, and/or the like. The heterostructure 2130 may be respectively formed by any suitable process (e.g., PVD, CVD, ALD, pulse laser deposition (PLD), metal doping, metal oxidization, or the like). In some embodiments, a thermal treatment (e.g., annealing or the like) is performed on the heterostructure 2130 after the deposition. For example, the thermal treatment may cause the lower metal oxide material 2131 to react with the upper metal oxide material 2132 so as to form the 2 DEG region 213G. In some embodiments, the thermal treatment includes annealing the lower metal oxide material 2131 and the upper metal oxide material 2132 at temperatures up to about 400° C. or below 400° C.

Taking a TiO₂/Al₂O₃ heterostructure for example, the formation of the heterostructure 2130 may include: depositing a bottom oxide film (e.g., aluminum-containing oxide film); depositing an ultra-thin metal film (e.g., titanium-containing film); depositing a capping oxide film (e.g., aluminum-containing oxide film); and performing a thermal treatment for metal oxide formation. During the thermal treatment, the ultra-thin metal film (e.g., titanium-containing film) may react with the bottom and capping oxide films (e.g., aluminum-containing oxide films). As an example, the chemical reaction may have the following chemical equation: 2TiO₂+Al₂O₂→2TiO_{1.5}+Al₂O₃. As shown in the chemical equation, the valence state of the titanium ions is reduced, and oxygen vacancies may be formed and surrounded by titanium ions. For example, the oxygen vacancies are formed on the TiO₂ surface to provide electron donor states and generate free electrons. The oxygen deficient surface may be conducting when the content of oxygen vacancies is high enough. The electrons in the 2 DEG region 213G may move freely in a direction parallel to the interface but are geometrically confined in the thickness direction of the heterostructure 2130. In some embodiments where the heterostructure 2130 is a TiO₂/Al₂O₃ heterostructure, the lower metal oxide material 2131 is the titanium-containing oxide film and the upper metal oxide material 2132 is the aluminum-containing oxide film. In alternative embodiments, the lower metal oxide material 2131 is the aluminum-containing oxide film and the upper metal oxide material 2132 is the titanium-containing oxide film.

With continued reference to FIG. 2B, the channel material layer 2140 may be formed by any suitable deposition process (e.g., PVD, CVD, ALD, or the like). In some embodiments, the channel material layer 2140 is formed after the formation of the 2 DEG region 213G in the heterostructure 2130. In some embodiments, the 2 DEG region 213G is formed during the deposition of the channel material layer 2140. The channel material layer 2140 may be a single layer or a multi-layered channel. The channel material layer 2140 includes an oxide semiconductor material, a group IV semiconductor material or a group III-V semiconductor material. The oxide semiconductor material may include In—Ga—Zn—O (IGZO), In—Ga—O (IGO), In—Zn—O (IZO), In—W—O (IWO), Sn-doped material (e.g., SnInZnO, SnInGaZnO, SnGaZnO, etc.), the like, combinations thereof, etc. In some embodiments, the channel material layer 2140 includes InₓGa_{y}Zn_{z}MO, where M includes Ti, Al, Ag, W, Ce, Sn, V, Sc, the like, and 0≤x/y/z≤1.

Still referring to FIG. 2B, the channel material layer 2140 may have a thickness 2140H ranging from about 30 angstroms to about 200 angstroms. It is realized that the thickness range is an example, and may be changed to other suitable values depending on product requirements. The thickness 212H of the gate dielectric layer 212 may be substantially equal to or greater than the thickness 2130H of the heterostructure 2130. In some embodiments, a ratio of the thickness 212H to the thickness 2130H is in a range of about 1 to about 15. The thickness 2140H of the channel material layer 2140 may be greater than the thickness 2130H of the heterostructure 2130. In some embodiments, a ratio of the thickness 2140H to the thickness 2130H is in a range of about 1.7 to about 10.

Referring to FIG. 2C and with reference to FIG. 2B, a capping material layer 2150 may be formed on the channel material layer 2140 by any suitable deposition process (e.g., PVD, CVD, ALD, or the like). The capping material layer 2150 may be formed of any suitable dielectric material (e.g., SiO₂ or the like), high-k dielectric material (e.g., HfO₂, Al₂O₃, TiO₂, or the like), combination thereof, or any suitable capping material(s). In some embodiments, the capping material layer 2150 has a thickness 2150H ranging from about 10 angstroms to about 200 angstroms. It is realized that the thickness range is an example, and may be changed to other suitable values depending on product requirements. In some embodiments, an oxygen treatment or a plasma treatment (e.g., with O₂ and/or O₃ as oxidant species) is performed on the capping material layer 2150. For example, plasma containing oxygen is used to treat (oxidize) the top surface of the capping material layer 2150. The top surface of the capping material layer 2150 may be passivated.

Referring to FIG. 2D and with reference to FIG. 2C, a patterning process may be performed to remove portions of the capping material layer 2150, the channel material layer 2140, and the heterostructure 2130 to respectively form a capping layer 215, the channel layer 214, and a heterostructure 213. The patterning process may include one or more lithography and etching processes or any suitable removal technique. In some embodiments, a patterned photoresist (not shown) is formed over the capping material layer 2150 to act as an etch mask, portions of the capping material layer 2150, the channel material layer 2140, and the heterostructure 2130 that are not covered by the patterned photoresist may be removed during the etching (e.g., a dry etch, a wet etch, or a combination thereof). The remaining portions of the capping material layer 2150, the channel material layer 2140, and the heterostructure 2130 may respectively form the capping layer 215, the channel layer 214, and the heterostructure 213. The patterned photoresist may then be removed through any suitable removal process including stripping, ashing, or the like. After the patterning process, at least a portion of the top surface 212t of the gate dielectric layer 212 may be accessibly exposed by the stack of the capping layer 215, the channel layer 214, and the heterostructure 213.

With continued reference to FIG. 2D, the sidewalls (215W, 214W, and 213W) of the capping layer 215, the channel layer 214, and the heterostructure 213 may be substantially leveled (or coplanar), within process variations. In some embodiments, the sidewalls (214W and 213W) of the channel layer 214 and the heterostructure 213 are substantially aligned and may be laterally offset from the sidewall 215W of the capping layer 215. In the cross-sectional view, the lateral dimensions (215L, 214L, and 213L) of the capping layer 215, the channel layer 214, and the heterostructure 213 may be less than the lateral dimension 212L of the gate dielectric layer 212.

Referring to FIG. 2E and with reference to FIG. 2D, a dielectric layer 361 may be formed on the top surface 212t of the gate dielectric layer 212 to cover the stack of the capping layer 215, the channel layer 214, and the heterostructure 213. The dielectric layer 361 may cover the top surfaces (215t and 212t) of the capping layer 215 and the gate dielectric layer 212 and may extend along the sidewalls (215W, 214W, and 213W) of the capping layer 215, the channel layer 214, and the heterostructure 213. The dielectric layer 361 may be a part of the dielectric layers 36 described in FIG. 1, and thus the material and the forming method of the dielectric layer 361 is not repeated herein. In some embodiments, the dielectric layer 361 has a thickness 361H ranging from about 50 angstroms to about 500 angstroms. It is realized that the thickness range is an example, and may be changed to other suitable values depending on product requirements.

Referring to FIG. 2F and with reference to FIG. 2E, contact openings 361P may be formed to expose at least a portion of the channel layer 214. For example, portions of the dielectric layer 361, the capping layer 215, and the channel layer 214 may be removed to form the contact openings 361P through one or more lithographic and etching processes or any suitable removal process. For example, a patterned photoresist (not shown) is formed on the dielectric layer 361 to be used as an etch mask so that portions of the dielectric layer 361, the capping layer 215, and the channel layer 214 uncovered by the patterned photoresist are removed during the etching process, and the patterned photoresist is then removed thorough a stripping process or ashing process. The depth of the respective contact opening 361P in the channel layer 214 may vary depending on product and process requirements. In some embodiments, the contact openings 361P expose the top surface 214t of the channel layer 214. In some embodiments, the contact openings 361P extend into the channel layer 214, and the surface 214s of the channel layer 214 below the top surface 214t is accessibly exposed by the contact openings 361P. In some embodiments, the contact openings 361P reach the top surface 213t of the heterostructure 213.

Referring to FIG. 2G and with reference to FIG. 2F, contact vias 216 may be formed in the contact openings 361P and may be in direct contact with the surface 214s of the channel layer 214. In some embodiments, the contact vias 216 are formed by depositing conductive material to fill up the contact openings 361P. The material of the contact vias 216 may be selected from the candidate material(s) for forming the gate layer 211. In some embodiments, a planarization process (e.g., chemical mechanical polishing (CMP), grinding, etching, a combination thereof, etc.) is performed on the contact vias 216 and the dielectric layer 361. For example, top surfaces (216t and 361t) of the contact vias 216 and the dielectric layer 361 are substantially leveled (or coplanar), within process variations. The dielectric layer 361 may laterally surround the upper portion of the respective contact via 216 which is protruded from the top surface 215t of the capping layer 215. The capping layer 215 may laterally surround the middle portion of the respective contact via 216 which is protruded from the top surface 214t of the channel layer 214. The channel layer 214 may laterally surround the lower portion of the respective contact via 216 which is between the top surface 214t and the surface 214s of the channel layer 214.

In some embodiments, the respective contact via 216 is formed with a thickness ranging from about 50 angstroms to about 500 angstroms. The vertical distance D1 measured between the top surface 213t of the heterostructure 213 and the surface 214s of the channel layer 214 (or the bottom surface 216b of the respective contact via 216) along the Z-direction may be in a range of 0 to about 2 nm. For example, the contact vias 216 are in direct contact with the top surface 213t of the heterostructure 213. In alternative embodiments where the channel layer 214 is thin enough (e.g., less than about 30 angstroms), the contact vias 216 land on the channel layer 214 to be in direct contact with the top surface 214t of the channel layer 214. It is realized that the thickness and the vertical distance ranges are an example, and may be changed to other suitable values depending on product requirements.

Up to here, the second semiconductor device T2 in the semiconductor structure 10 is obtained. The second semiconductor device T2 may include a stacked structure including the gate layer 211, the gate dielectric layer 212, the heterostructure 213, the channel layer 214, and the capping layer 215 sequentially stacked from the bottom to the top, and the contact vias 216 located on the stacked structure. In some embodiments, the contact vias 216 function as the S/D electrodes of the second semiconductor device T2. In some embodiments, the gate layer 211 is referred to as a word line, and a pair of contact vias 216 is respectively referred to a source line and a bit line. The contact vias 215 may be further electrically coupled to the conductive patterns 34 and/or the conductive vias 32 of the interconnection structure 30 (shown in FIG. 1).

With continued reference to FIG. 2G, the second semiconductor device T2 including 2 DEG region 213G may function as a HEMT, where the 2 DEG region 213G act as a part of the carrier channel for the HEMT. As mentioned in FIG. 2B, the oxygen vacancies may donate free electrons 213E generated at the heterojunction of the heterostructure 213. When the second semiconductor device T2 is in an on state, a current may flow along the 2 DEG region 213G and also flow in the channel layer 214. For example, the electrons 213E in the 2 DEG region 213G may be confined to only move in two directions (e.g., the X-direction and the Y-direction) which form a plane are parallel to the interface of the heterostructure 213, and may be confined in the Z-direction. The electrons in the channel layer 214 may move freely in three dimensions (e.g., the X-direction, the Y-direction, and the Z-direction). When the second semiconductor device T2 is on, the electrons in the 2 DEG region 213G may exhibit high mobility which is essential to generate ballistic electrons. For example, the electron mobility of the second semiconductor device T2 may be greater than 15 cm²/Vs. The second semiconductor device T2 may have greater electron mobility in comparison to the HEMT without the heterostructure 213.

The 2 DEG region 213G in the heterostructure 213 of the second semiconductor device T2 may be in a short-range order phase or may be referred to as the short-range order layer. The term “short-range order” refers to regular and predictable arrangement of atoms only over a short distance, and this regularity does not persist over a long distance. For example, the atoms in the 2 DEG region 213G is neither in an amorphous state nor in a crystalline state. Instead, the atoms in the 2 DEG region 213G are in a state between the amorphous state and the crystalline state. The 2 DEG region 213G may be an amorphous-like film (low crystallinity). This may help to improve the oxide quality by reducing the defects in dielectric, thereby improving device leakage performance.

The 2 DEG region 213G may be a layer of highly mobile, highly concentrated electrons at the heterojunction in the heterostructure 213. Due to the hetero-interface properties, the interface between the heterostructure 213 and the channel layer 214 and the interface between the heterostructure 213 and the gate dielectric layer 212 may be clearly distinguishable. The hetero-interface properties may be beneficial for less interface traps among the channel layer 214, the heterostructure 213, and the gate dielectric layer 212, leading good bias stress reliability during the BEOL process. Since the electrons 213E are confined to only move in the 2 DEG region 213G, the upper metal oxide material 2132 does not interact with the channel layer 214. There is no intermixing region formed between the interface of the channel layer 214 and the heterostructure 213 so that defect generation in the channel layer 214 may be suppressed. By configuring the 2 DEG region 213G between the channel layer 214 and the gate dielectric layer 212, the threshold voltage for the second semiconductor device T2 may be controlled and the likelihood of unwanted shift of the electrical characteristics (e.g., on-current or the like) may be reduced or eliminated. The mobility and electrical performance of the second semiconductor device T2 may be enhanced.

FIG. 3 illustrates a schematic perspective view of a second semiconductor device in a semiconductor structure, in accordance with some embodiments. Unless explicitly stated otherwise, the materials and the formation methods of the components in these embodiments are essentially the same as the like components, which are denoted by like reference numerals in the embodiments described in accompanying with FIGS. 2A-2G.

Referring to FIG. 3, a three-dimensional device array 400 may include stacks of second semiconductor devices T2-1 arranged in columns respectively extending along the Y-direction (also referred as a column direction). These columns are arranged along the X-direction (also referred as a row direction) intersected with the Y-direction. In order to clearly illustrate elements in each stack of the second semiconductor devices T2-1, a stack of the second semiconductor devices T2-1 in one of these columns are particularly depicted. Although not shown, there are actually other stacks of the second semiconductor devices T2-1 in this column. In some embodiments, each stack of the second semiconductor devices T2-1 contain a segment of a stacking structure, and a plurality of the stacking structures 410 extend along the column direction (i.e., the Y-direction), and are laterally spaced apart from one another along the row direction (i.e., the X-direction). The stacks of the second semiconductor devices T2-1 in the same column share the same stacking structure 410, and each stacking structure 410 may be shared by the stacks of the second semiconductor devices T2-1 in adjacent columns.

The gate layers 211 and isolation layers 362 may be alternately stacked along a vertical direction Z in each stacking structure 410. In some embodiments, the gate layers 211 are referred to word lines. The gate layers 211 may include conductive material(s) similar to the gate layer 211 described in FIG. 2A. In some embodiments, end portions of the stacking structures 410 are shaped into staircase structures 411, and the gate layers 211 extend to steps of the staircase structures 411. In some embodiments, an end portion of each gate layer 211 in the respective stacking structure 410 (except for the topmost gate layer 211) laterally protrudes with respect to an end portion of an overlying gate layer 211 in the same stacking structure 410 along the Y-direction, to form a step of the staircase structure 411. Each of the gate layers 211 may have an end portion not covered by others of the gate layers 211, thus may be independently out-routed.

With continued reference to FIG. 3, the isolation layers 362 may be formed of an insulating material (e.g., silicon oxide, silicon nitride, silicon oxynitride, etc.) and may be a part of the dielectric layers 36 of the interconnect structure 30 described in FIG. 1. In some embodiments, an end portion of each isolation layer 362 in the respective stacking structure 410 is aligned with an end portion of an overlying gate layer 211, and defines a bottom portion of a step. For example, each step of the staircase structure 411 consists of end portions of one of the gate layers 211 and the underlying isolation layer 362. The gate dielectric layers 212 may span along sidewalls of the stacking structures 410. In some embodiments, each gate dielectric layer 212 covers opposing sidewalls of adjacent stacking structures 410. The material of the gate dielectric layer 212 may be similar to the gate dielectric layer 212 described in FIG. 2A.

With continued reference to FIG. 3, the heterostructure 213 may cover surfaces of the gate dielectric layer 212 facing toward trenches between the stacking structures 410. The channel layers 214 may cover surfaces of the heterostructure 213 such that the heterostructure 213 is sandwiched between the gate dielectric layer 212 and the channel layer 214 in the X-direction. In some embodiments, each channel layer 214 is exclusively shared by a stack of the second semiconductor devices T2-1. The channel layers 214 at opposing sidewalls of adjacent stacking structures 410 may be laterally spaced apart. The materials of the heterostructure 213 and the channel layers 214 may be similar to the heterostructure 213 and the channel layers 214 described in FIG. 2B. In the illustrated embodiment, the capping layer 215 described in FIG. 2C is excluded in the second semiconductor devices T2-1. Alternatively, the capping layer 215 is formed to cover surfaces of the channel layers 214 in the second semiconductor devices.

In some embodiments, pairs of S/D electrodes 216 are formed in a pillar shape and the S/D electrodes 216 in each pair are separately in lateral contact with the channel layer(s) 214 covering opposing sidewalls of adjacent stacking structures 410. The adjacent pairs of the S/D electrodes 216 arranged along the Y-direction may be laterally separated. The S/D electrodes 216 may be similar to the contact vias 216 described in FIG. 2G. In some embodiments, the S/D electrodes 216 are respectively referred to as a source line and a bit line. In some embodiments, the dielectric layers 361 acting as isolation structures are respectively filled between the S/D electrodes 216 of each pair, so as to isolate the S/D electrodes 216 of each pair from one another. In some embodiments, the channel layers 214 disposed along a sidewall of one of the stacking structures 410 are separated from one another by the dielectric layers 361 standing aside the respective stacking structure 410. In some embodiments, pairs of the S/D electrodes 216 at a side of the respective stacking structure 410 are offset along the Y-direction from pairs of the S/D electrodes 216 at the other side of the stacking structure 410. For example, the stacks of second semiconductor devices T2-1 are referred as being arranged in a staggered configuration.

Still referring to FIG. 3, a segment of one of the gate layers 211 and portions of the gate dielectric layer 212, the heterostructure 213, the channel layer 214, and a pair of S/D electrodes 216 in lateral contact with the segment of the gate layer 211 collectively form one of the second semiconductor devices T2-1, which may be a field effect transistor (FET). When the FET is turned on, a conduction channel may be formed in the portions of the heterostructure 213 and the channel layer 214, and extend between the pair of the S/D electrodes 216. When the FET is in an off state, the conduction channel may be cut off or absent. In an embodiment, the second semiconductor device T2 of the semiconductor structure 10 shown in FIG. 1 is replaced with the three-dimensional device array 400. The semiconductor structure 10 shown in FIG. 1 may include any combination of the second semiconductor devices (e.g., T2 and T2-1).

The respective second semiconductor device T2-1 may include the heterostructure 213 separating the channel layer 214 from the gate dielectric layer 212. The heterostructure 213 includes the 2 DEG region which is a layer of highly mobile, highly concentrated electrons at the heterojunction in the heterostructure 213. As mentioned in FIG. 2G, the free electrons in the 2 DEG region are confined to only move at the 2 DEG region 213G, the heterostructure 213 does not interact with the overlying channel layer 214 and the underlying gate dielectric layer 212 so that defect generation in the channel layer 214 and the gate dielectric layer 212 may be suppressed. The 2 DEG region in the heterostructure 213 may be an amorphous-like film for improving the oxide quality by reducing the defects in dielectric, thereby improving device leakage performance. Due to the hetero-interface properties of the heterostructure 213, less interface traps among the channel layer 214, the heterostructure 213, and the gate dielectric layer 212 may be achieved, leading good bias stress reliability during the BEOL process. The mobility and electrical performance of the second semiconductor device T2 may be enhanced.

According to some embodiments, a semiconductor structure includes an interconnect structure over a substrate and a transistor embedded in the interconnect structure. The transistor includes at least one gate layer, a gate dielectric layer extending along the at least one gate layer, a channel layer extending along the gate dielectric layer, a heterostructure interposed between the gate dielectric layer and the channel layer, and source/drain vias connected to the channel layer. The heterostructure includes a 2 DEG region acting as a part of a channel of the transistor.

According to some embodiments, a semiconductor structure includes a transistor embedded in an interconnect structure over a substrate. The transistor includes a gate electrode, a gate dielectric layer overlying the gate electrode, a channel layer over the gate dielectric layer, a 2 DEG region interposed between the channel layer and the gate dielectric layer, and S/D electrodes connected to the channel layer. The 2 DEG region acts as a part of a channel of the transistor, where free electrons in the 2 DEG region move in two dimensions and are confined in a thickness direction of the 2 DEG region.

According to some embodiments, a method for forming a semiconductor structure includes forming a transistor in an interconnect structure over a substrate. Forming the transistor includes: forming a gate dielectric layer on a gate layer, forming a heterostructure on the gate dielectric layer, wherein the heterostructure comprises a 2 DEG region which acts as a part of a channel of the transistor; forming a channel layer on the heterostructure; and forming S/D vias on the channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an interconnect structure over a substrate; and
a transistor embedded in the interconnect structure and comprising:
at least one gate layer;
a gate dielectric layer extending along the at least one gate layer;
a channel layer extending along the gate dielectric layer;
a heterostructure interposed between the gate dielectric layer and the channel layer, the heterostructure comprising a two-dimensional electron gas (2 DEG) region which acts as a part of a channel of the transistor; and
source/drain (S/D) vias connected to the channel layer.

2. The semiconductor structure of claim 1, wherein the heterostructure comprises a first metal oxide material overlying the gate dielectric layer, a second metal oxide material underlying the channel layer and different from the first metal oxide material, and the 2 DEG region located at an interface between the first and second metal oxide materials.

3. The semiconductor structure of claim 1, wherein a material of the channel layer is different from the first and second metal oxide materials of the heterostructure.

4. The semiconductor structure of claim 1, wherein free electrons in the heterostructure move in a direction parallel to an interface of the heterostructure and are geometrically confined in a thickness direction of the heterostructure.

5. The semiconductor structure of claim 4, wherein free electrons in the channel layer move in three dimensions.

6. The semiconductor structure of claim 1, wherein bottom surfaces of the S/D vias are between a top surface of the channel layer and a top surface of the heterostructure.

7. The semiconductor structure of claim 1, wherein sidewalls of the channel layer and the heterostructure are substantially coplanar.

8. The semiconductor structure of claim 1, wherein a thickness of the channel layer is greater than that of the heterostructure.

9. The semiconductor structure of claim 1, wherein an effective thickness of the 2 DEG region is in a range of 80 percent and 100 percent of an overall thickness of the heterostructure.

10. The semiconductor structure of claim 1, wherein:
the at least one gate layer comprises a plurality of gate layers, the gate layers and isolation layers are alternately stacked to form a stacking structure,
the gate dielectric layer covering a sidewall of the stacking structure, and
the S/D vias separately stand aside the stacking structure and are in lateral contact with the channel layer.

11. The semiconductor structure of claim 1, wherein the transistor further comprises:
a capping layer overlying the channel layer, wherein the S/D vias penetrate through the capping layer and extend into the channel layer.

12. The semiconductor structure of claim 1, wherein the interconnect structure comprises a dielectric layer and a conductive pattern embedded in the dielectric layer, and the transistor is embedded in the dielectric layer and electrically coupled to the conductive pattern.

13. A semiconductor structure, comprising:
a transistor embedded in an interconnect structure over a substrate, the transistor comprising:
a gate electrode;
a gate dielectric layer overlying the gate electrode;
a channel layer over the gate dielectric layer;
a two-dimensional electron gas (2 DEG) region interposed between the channel layer and the gate dielectric layer, the 2 DEG region acting as a part of a channel of the transistor, wherein free electrons in the 2 DEG region move in two dimensions and are confined in a thickness direction of the 2 DEG region; and
S/D electrodes connected to the channel layer.

14. The semiconductor structure of claim 13, wherein the transistor further comprises:
a heterostructure comprising an upper metal oxide material underlying the channel layer and a lower metal oxide material overlying the gate dielectric layer, wherein the 2 DEG region is an intermixing region between the upper and lower metal oxide materials.

15. The semiconductor structure of claim 13, wherein the 2 DEG region is a short-range order layer.

16. The semiconductor structure of claim 13, wherein the transistor is a high electron mobility transistor.

17. A manufacturing method of a semiconductor structure, comprising:
forming a transistor in an interconnect structure over a substrate comprising:
forming a gate dielectric layer on a gate layer;
forming a heterostructure on the gate dielectric layer, wherein the heterostructure comprises a two-dimensional electron gas (2 DEG) region which acts as a part of a channel of the transistor;
forming a channel layer on the heterostructure; and
forming S/D vias on the channel layer.

18. The manufacturing method of claim 17, wherein forming the heterostructure comprises:
forming a first metal oxide material on the gate dielectric layer;
forming a second metal oxide material on the first metal oxide material;
performing a thermal treatment on the first and second metal oxide materials, wherein after the thermal treatment, the 2 DEG region is formed at a heterojunction of the first and second metal oxide materials.

19. The manufacturing method of claim 18, wherein performing the thermal treatment comprises:
annealing the first and second metal oxide materials at a temperature below about 400° C.

20. The manufacturing method of claim 18, wherein materials and forming processes of the heterostructure are compatible with a back-end-of-line (BEOL) process.
